(19) United States
(12) Patent Application Publication
(10) Pub. No.: US 2024/0074129 A1
(43) Pub. Date: Feb. 29, 2024

(54) Induction Heating with Reduced Magnetic Fields

(71) Applicant: The Boeing Company, Arlington, VA (US)

(72) Inventors: Bret Alan Mcginness Voss, Seattle, WA (US); Marc R. Matsen, Seattle, WA (US)

(21) Appl. No.: 18/307,478

(22) Filed: Apr. 26, 2023

Related U.S. Application Data
(60) Provisional application No. 63/373,672, filed on Aug. 26, 2022.

(51) Int. Cl. H05K 9/00; H05B 6/10; H05B 6/44

(52) U.S. Cl. CPC H05K 9/0075; H05B 6/105; H05B 6/44; H05K 9/0071; H05B 2206/023

(57) ABSTRACT

An induction heating system and methods of forming an induction heating system are presented. The induction heating system comprises a conductor, a susceptor surrounding the conductor, and magnetic field reduction. The susceptor has a Curie temperature. The magnetic field reduction is configured to reduce magnetic fields escaping the induction heating system when the susceptor is at the Curie temperature independent of a layout of the induction heating system within an induction heating device.

### CROSS-REFERENCE TO RELATED APPLICATION

This application claims the benefit of U.S. Provisional Patent Application Ser. No. 63/373,672, filed Aug. 26, 2022, and entitled “Induction Heating with Reduced Magnetic Fields,” which is incorporated herein by reference in its entirety.

### BACKGROUND INFORMATION

### 1. Field

The present disclosure relates generally to methods and equipment for out-of-autoclave curing of composite parts, and deals more particularly with a method and equipment for induction heating with reduced magnetic fields outside of the induction heating circuit.

### 2. Background

In conventional induction heating circuits, the flow of alternating current through a conductor of the circuit results in a magnetic field. The susceptor and conductor are designed such that at temperatures below the Curie temperature of the susceptor, the magnetic field is concentrated in the susceptor due to its magnetic permeability.

Upon reaching Curie temperature, susceptor becomes non-ferromagnetic. The magnetic fields are no longer concentrated in the susceptor when the susceptor becomes non-ferromagnetic. Magnetic fields escape conventional induction heating circuits when the susceptors reach a respective Curie temperature.

FCC regulations include electromagnetic emission regulations. Currently, induction heating circuits are arranged in parallel circuit patterns to cancel long range electromagnetic effects from adjacent circuits to remain below FCC regulated limits of magnetic fields. In some instances, lower frequency is used in induction heating circuits to remain below FCC regulated limits of magnetic fields.

Therefore, it would be desirable to have a method and apparatus that takes into account at least some of the issues discussed above, as well as other possible issues. For example, it would be desirable to have greater flexibility in induction heating circuit layout. In some instances, it would be desirable to use higher frequency power sources.

### SUMMARY

An embodiment of the present disclosure provides an induction heating system. The induction heating system comprises a conductor, a susceptor surrounding the conductor, and a magnetic field reduction. The susceptor has a Curie temperature. The magnetic field reduction is configured to reduce magnetic fields escaping the induction heating system when the susceptor is at the Curie temperature independent of a layout of the induction heating system within an induction heating device.

Another embodiment of the present disclosure provides an induction heating circuit. The induction heating circuit comprises a conductor, a susceptor having a Curie temperature surrounding the conductor, and a shielding of conductive metal surrounding the susceptor and the conductor configured to reduce magnetic fields escaping the induction heating circuit when the susceptor is at the Curie temperature.

Another embodiment of the present disclosure provides an induction heating system. The induction heating system comprises a first induction heating circuit having a first current direction, and a second induction heating circuit twisted around the first induction heating circuit and a central axis. The second induction heating circuit has a second current direction opposite of the first current direction.

A further embodiment of the present disclosure provides a method of reducing magnetic fields escaping an induction heating system during induction heating. An induction heating circuit is surrounded with shielding. The induction heating circuit comprises a conductor and a susceptor surrounding the conductor. The susceptor has a Curie temperature, and the shielding is configured to reduce magnetic fields escaping the induction heating circuit when the susceptor is at the Curie temperature. The induction heating circuit is positioned into a layout in an induction heating device to form the induction heating system.

Yet another embodiment of the present disclosure provides method of reducing magnetic fields escaping an induction heating system during induction heating. A first induction heating circuit and a second induction heating circuit are wrapped around a central axis to form a pair of induction heating circuits twisted around the central axis, the pair of induction heating circuits having opposite current directions. Power is applied to the first induction heating circuit and the second induction heating circuit. The magnetic fields from each of the first induction heating circuit and the second induction heating circuit are canceled out by the opposite current directions as power is applied to the first induction heating circuit and the second induction heating circuit.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of an aircraft in which an illustrative embodiment may be implemented;

FIG. 2 is an illustration of a block diagram of a manufacturing environment in which an illustrative embodiment may be implemented;

FIG. 3 is an illustration of a cross-sectional view of an induction heating circuit in accordance with an illustrative embodiment;

FIG. 4 is an illustration of a cross-sectional view of an induction heating circuit in accordance with an illustrative embodiment;

FIG. 5 is an illustration of a partially exploded view of an induction heating circuit with spiral shielding in accordance with an illustrative embodiment;

FIG. 6 is an illustration of a partially exploded view of an induction heating circuit with foil shielding in accordance with an illustrative embodiment;

FIG. 7 is an illustration of a partially exploded view of an induction heating circuit with braided shielding in accordance with an illustrative embodiment;

FIG. 8 is an illustration of a partially exploded view of an induction heating circuit with foil and braided shielding in accordance with an illustrative embodiment;

FIG. 9 is an illustration of a side view of an induction heating system with a twisted pair of induction heating circuits in accordance with an illustrative embodiment;

FIG. 10 is an illustration of a cross-sectional view of an induction heating system with a twisted pair of induction heating circuits in accordance with an illustrative embodiment;

FIG. 11 is an illustration of a cross-sectional view of an induction heating system with a twisted pair of induction heating circuits in accordance with an illustrative embodiment;

FIG. 12 is a flowchart of a method of reducing magnetic fields escaping an induction heating system during induction heating in accordance with an illustrative embodiment;

FIG. 13 is a flowchart of a method of reducing magnetic fields escaping an induction heating system during induction heating in accordance with an illustrative embodiment;

FIG. 14 is an illustration of an aircraft manufacturing and service method in a form of a block diagram in accordance with an illustrative embodiment; and

FIG. 15 is an illustration of an aircraft in a form of a block diagram in which an illustrative embodiment may be implemented.

### DETAILED DESCRIPTION

The illustrative examples recognize and take into account one or more different considerations. The illustrative examples recognize and take into account that a composite part can be cured in an oven or an autoclave where heat is applied to the part while supported on a cure tool that maintains the shape of the part during the curing process. The illustrative examples recognize and take into account that curing the composite material using an autoclave may use at least one of undesirable amount of time or an undesirable amount of energy.

The illustrative examples recognize and take into account that induction heating techniques have been developed for curing composite parts without the need for an oven or autoclave, however these techniques have been limited by the frequency of the induction current and the design of the induction tools.

The illustrative examples recognize and take into account that higher frequency power supplies generate higher currents which can generate high electromagnetic emissions. The illustrative examples recognize and take into account that electromagnetic noise could interfere with electronics. The illustrative examples also recognize and take into account that there are FCC regulations regarding electromagnetic emissions. The illustrative examples recognize and take into account that eddy currents can undesirably generate heat in surrounding materials.

The illustrative examples recognize and take into account that conventional induction heating circuits are arranged in parallel circuit patterns to cancel electromagnetic effect from adjacent circuits. The illustrative examples recognize and take into account that currently lower frequency is used in induction heating circuits to remain below FCC regulated limits of magnetic fields.

The illustrative examples recognize and take into account that it may be desirable to utilize power supplies with higher frequencies without generating high electromagnetic emissions. The illustrative examples recognize and take into account that it would be desirable to have greater flexibility in the design of induction heating tools.

The illustrative examples provide an induction heating system. The induction heating system comprises a conductor, a susceptor surrounding the conductor, and a magnetic field reduction. The susceptor has a Curie temperature. The magnetic field reduction is configured to reduce magnetic fields escaping the induction heating system when the susceptor is at the Curie temperature independent of a layout of the induction heating system within an induction heating device. The illustrative examples provide greater flexibility in the layout of induction heating circuits. The illustrative examples provide an induction heating system that generates lower electromagnetic emission.

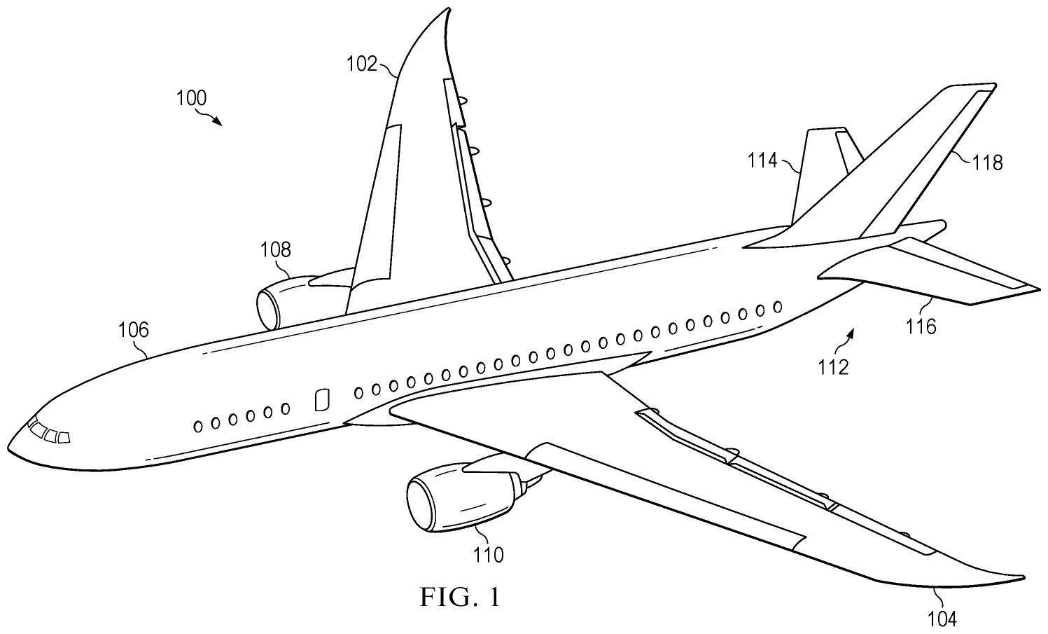

Turning now to FIG. 1, an illustration of an aircraft is depicted in accordance with an illustrative embodiment. Aircraft 100 has wing 102 and wing 104 attached to body 106. Aircraft 100 includes engine 108 attached to wing 102 and engine 110 attached to wing 104.

Body 106 has tail section 112. Horizontal stabilizer 114, horizontal stabilizer 116, and vertical stabilizer 118 are attached to tail section 112 of body 106.

Aircraft 100 is an example of an aircraft having large composite components that can be manufactured using an induction heating system having magnetic field reduction. For example, portions of body 106, wing 102, or wing 104 can be manufactured using an induction heating system having magnetic field reduction.

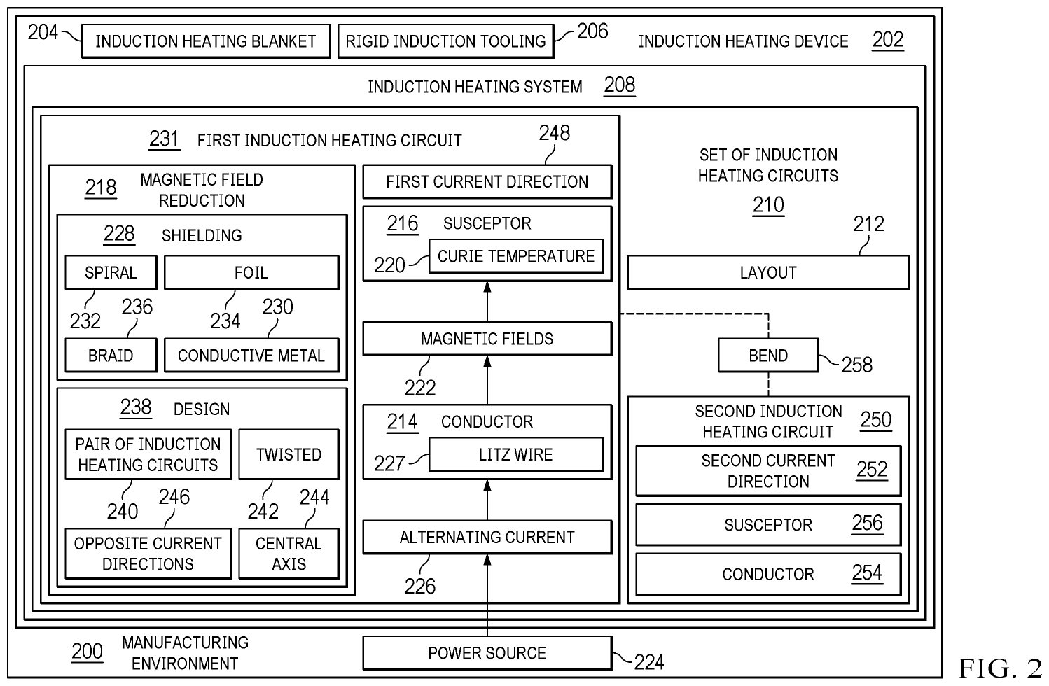

Turning now to FIG. 2, an illustration of a block diagram of a manufacturing environment is depicted in which an illustrative embodiment may be implemented. Manufacturing environment 200 is a manufacturing environment in which a component of aircraft 100 can be manufactured. For example, a portion of body 106, wing 102, or wing 104 could be manufactured using induction heating device 202 in manufacturing environment 200.

Induction heating device 202 can take the form of induction heating blanket 204 or rigid induction tooling 206. Induction heating device 202 comprises induction heating system 208 to provide heat in induction heating device 202. Induction heating system 208 comprises set of induction heating circuits 210 having layout 212 in induction heating device 202. As used herein, a “set of” items is one or more items. For example, set of induction heating circuits 210 is one or more induction heating circuits.

Induction heating system 208 comprises conductor 214, susceptor 216 surrounding conductor 214, and magnetic field reduction 218. Susceptor 216 has Curie temperature 220. Magnetic field reduction 218 is configured to reduce magnetic fields 222 escaping induction heating system 208 when susceptor 216 is at Curie temperature 220 independent of layout 212 of induction heating system 208 within induction heating device 202.

Magnetic field reduction 218 allows layout 212 of set of induction heating circuits 210 to deviate from conventional parallel designs without unacceptable emissions of magnetic fields 222. Magnetic field reduction 218 allows layout 212 of set of induction heating circuits 210 to be non-serpentine.

In some illustrative examples, positioning set of induction heating circuits into layout 212 comprises positioning set of induction heating circuits into layout 212 that is non-serpentine. Magnetic field reduction 218 enables non-serpentine layouts of set of induction heating circuits 210 without undesirable quantities of magnetic emissions.

Susceptor 216 comprises a metal, an alloy, or any other suitable material that is electrically conducting and having Curie temperature 220 in a range for performing a desired operation on a material. In some illustrative examples, susceptor 216 comprises at least one of iron, cobalt, nickel, molybdenum, or chromium.

Power source 224 provides alternating current 226 to conductor 214. Conductor 214 receives alternating current 226 and generates magnetic fields 222 in response to alternating current 226. Conductor 214 comprises any desirable material having low electrical resistance. In some illustrative examples, conductor 214 is formed of a flexible material to enable use of first induction heating circuit 231 in induction heating blanket 204. In some illustrative examples, conductor 214 is formed of a flexible material to enable the use of conductor 214 in curved surfaces. In some illustrative examples, conductor 214 comprises Litz wire 227.

Susceptor 216 is a magnetic material located adjacent to conductor 214. The magnetic material generates heat in response to magnetic fields 222. Curie temperature 220 is a temperature at which susceptor 216 becomes non-ferromagnetic. The heating of susceptor 216 due to magnetic fields 222 ceases when susceptor 216 reaches Curie temperature 220.

Susceptor 216 may be referred to as a “smart susceptor”. Susceptor 216 extends along conductor 214. In some illustrative examples, susceptor 216 is coaxially mounted to conductor 214 and electrically insulated from conductor 214 for induction heating in response to magnetic fields 222.

In some illustrative examples, magnetic field reduction 218 comprises shielding 228 surrounding susceptor 216. Shielding 228 blocks magnetic fields 222 from escaping first induction heating circuit 231. By blocking magnetic fields 222, shielding 228 reduces magnetic fields 222 escaping induction heating system 208.

Shielding 228 is formed of conductive metal 230. Conductive metal 230 is selected based on at least one of conduction, cost, and manufacturability. In some illustrative examples, conductive metal 230 is selected from copper or aluminum. In some illustrative examples, shielding 228 comprises copper or aluminum.

In some illustrative examples, shielding 228 physically blocks magnetic fields 222 from exiting first induction heating circuit 231 after susceptor 216 reaches Curie temperature 220. In some illustrative examples, shielding 228 blocks magnetic fields 222 from exiting first induction heating circuit 231 using an induced current with an opposing field in shielding 228 after susceptor 216 reaches Curie temperature 220.

In some illustrative examples, slight heating can occur in shielding 228 when using an induced current to block magnetic fields 222. The low electrical resistance of conductive metal 230 of shielding 228 is selected to reduce heating occurring in shielding 228 when a current is applied. In some illustrative examples, shielding 228 comprises a combination of physical blocking of magnetic fields 222 and current induced blocking of magnetic fields 222. In these illustrative examples, the ratio and combination of physical blocking and current induced blocking is engineered based on the application.

In some illustrative examples, shielding 228 comprises spiral 232 of conductive metal 230. In some illustrative examples, shielding 228 comprises foil 234 of conductive metal 230. In some illustrative examples, shielding 228 comprises braid 236 of conductive metal 230.

In some illustrative examples, magnetic field reduction 218 comprises design 238 of pair of induction heating circuits 240 twisted 242 around central axis 244. Pair of induction heating circuits 240 have opposite current directions 246. First induction heating circuit 231 of pair of induction heating circuits 240 comprises conductor 214 and susceptor 216 and has first current direction 248. Second induction heating circuit 250 having second current direction 252 comprises susceptor 256 and conductor 254.

In some illustrative examples, induction heating system 208 comprises first induction heating circuit 231 having first current direction 248 and a second induction heating circuit 250 twisted 242 around first induction heating circuit 231 and central axis 244, the second induction heating circuit 250 having a second current direction 252.

In some illustrative examples, twisted 242 pair of induction heating circuits 240 generates a higher magnetic field (B) intensity. In these illustrative examples, the space between the wires will have 2×B. Higher magnetic field intensity will increase Curie temperature 220 drop-off and improve ‘smartness’ of twisted 242 pair of induction heating circuits 240.

Design 238 of twisted 242 pair of induction heating circuits 240 provides cancellation of magnetic fields 222. Field intensity between first induction heating circuit 231 and second induction heating circuit 250 increases, but the direction changes as each of the induction heating circuits twist. In some illustrative examples, the sum of magnetic fields for first induction heating circuit 231 and second induction heating circuit 250 is closer to zero than conventional parallel wire designs.

In some illustrative examples, first induction heating circuit 231 and second induction heating circuit 250 are connected by bend 258 such that first induction heating circuit 231 and second induction heating circuit 250 are formed by a same conductor and a same susceptor surrounding the conductor. In these illustrative examples, susceptor 216 and susceptor 256 are formed of a single length of susceptor. In these illustrative examples, induction heating system 208 comprises a bend such that pair of induction heating circuits 240 is formed of conductor 214 and susceptor 216.

In some illustrative examples, pair of induction heating circuits 240 comprises second induction heating circuit 250 comprising a second conductor, conductor 254, and a second susceptor, susceptor 256. In these illustrative examples, first induction heating circuit 231 and second induction heating circuit 250 have independent lengths of susceptor and independent lengths of conductor.

In some illustrative examples, first induction heating circuit 231 comprises conductor 214; susceptor 216 having Curie temperature 220 surrounding conductor 214; and shielding 228 of conductive metal 230 surrounding susceptor 216 and conductor 214. Shielding 228 is configured to reduce magnetic fields 222 escaping first induction heating circuit 231 when susceptor 216 is at Curie temperature 220.

In some illustrative examples, first induction heating circuit 231 and second induction heating circuit 250 are formed by separate lengths of conductor surrounded by susceptor, first induction heating circuit 231 and second induction heating circuit 250 having separate electrical buses. In these illustrative examples, susceptor 216 is a separate length from susceptor 256. In these illustrative examples, conductor 214 is a separate length from conductor 254.

In some illustrative examples, first induction heating circuit 231 and the second induction heating circuit each comprise shielding 228 configured to reduce magnetic fields escaping a respective induction heating circuit when a respective susceptor is at a Curie temperature of the respective susceptor. Shielding 228 for each of first induction heating circuit 231 and second induction heating circuit 250 comprises conductive metal and is at least one of a braid, a foil, or a spiral.

Magnetic field reduction 218 enables larger spacing between adjacent portions of set of induction heating circuits 210 without undesirable magnetic emissions. Magnetic field reduction 218 enables layout 212 that is non-serpentine without undesirable magnetic emissions. Magnetic field reduction 218 also enables larger diameter set of induction heating circuits 210 without undesirable magnetic emissions. Magnetic field reduction 218 enables use of higher frequency power source 224 without undesirable magnetic emissions. Use of larger diameter set of induction heating circuits 210 with greater spacing in layout 212 can reduce manufacturing difficulty and manufacturing costs of rigid induction tool 206. Set of induction heating circuits 210 are placed into milled grooves in rigid induction tool 206. Reducing the quantity of the milled grooves reduces at least one of manufacturing difficulty or manufacturing costs of rigid induction tool 206. Reducing the difficulty of the layout of the milled grooves reduces at least one of manufacturing difficulty or manufacturing costs of rigid induction tool 206.

The illustration of induction heating device 202 in FIG. 2 is not meant to imply physical or architectural limitations to the manner in which an illustrative embodiment may be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

For example, thermal sensors can be present in induction heating device 202. As another example, second induction heating circuit 250 may be optional.

As another example, although shielding 228 is depicted as associated with first induction heating circuit 231, shielding 228 can be associated with any desirable induction heating circuits in set of induction heating circuits 210. In some illustrative examples, each of first induction heating circuit 231 and second induction heating circuit 250 has separate shielding 228. For example, first induction heating circuit 231 can have shielding 228 around conductor 214 and susceptor 216 while second induction heating circuit 250 has a separate length of shielding 228 around susceptor 256 and conductor 254. In some illustrative examples, shielding 228 wraps around both first induction heating circuit 231 and second induction heating circuit 250 such that shielding 228 encompasses susceptor 216, conductor 214, susceptor 256, and conductor 254. When shielding 228 encircles both first induction heating circuit 231 and second induction heating circuit 250, shielding 228 may be referred to as “shared shielding” for first induction heating circuit 231 and second induction heating circuit 250. A diameter of shielding 228 that is shared by both first induction heating circuit 231 and second induction heating circuit 250 is greater than a diameter of shielding 228 that encircles first induction heating circuit 231 and second induction heating circuit 250 individually.

In these illustrative examples, first induction heating circuit 231 and second induction heating circuit 250 are twisted 242 pair of induction heating circuits 240. In some illustrative examples, shielding 228 surrounds twisted 242 pair of induction heating circuits 240, shielding 228 configured to reduce magnetic fields 222 escaping twisted 242 pair of induction heating circuits 240 when twisted 242 pair of induction heating circuits 240 is at Curie temperature 220 of twisted 242 pair of induction heating circuits 240.

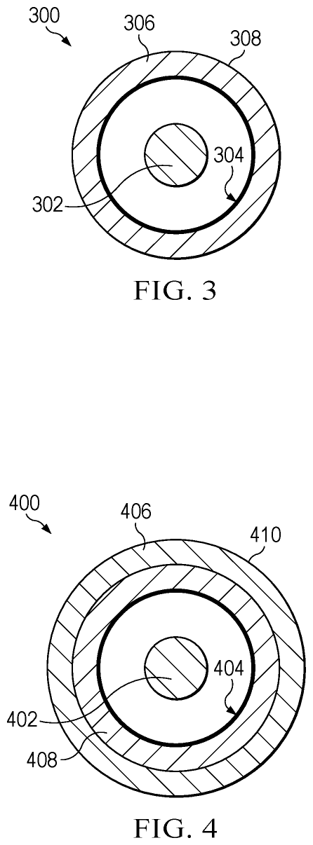

Turning now to FIG. 3, an illustration of a cross-sectional view of an induction heating circuit is depicted in accordance with an illustrative embodiment. Induction heating circuit 300 is a physical implementation of first induction heating circuit 231 of FIG. 2.

Induction heating circuit 300 comprises conductor 302, susceptor 304, and magnetic field reduction 306. Susceptor 304 surrounds conductor 302. Susceptor 304 is coaxial with conductor 302. Although susceptor 304 is depicted as a sleeve, susceptor 304 can take any desirable form. In some illustrative examples, susceptor 304 takes the form of a spiral, a coil, multiple short sleeves, or any other desirable form to surround conductor 302.

Magnetic field reduction 306 is configured to reduce magnetic fields escaping induction heating circuit 300 when susceptor 304 is at the Curie temperature independent of a layout of an induction heating system having induction heating circuit 300. Magnetic field reduction 306 takes the form of shielding 308. Shielding 308 surrounds susceptor 304. Shielding 308 is a conductive metal and is one of a spiral, a braid, or a foil. Shielding 308 blocks magnetic fields from exiting induction heating circuit 300 after susceptor 304 reaches its Curie temperature through at least one of physically blocking or blocking the magnetic fields using induced currents.

Turning now to FIG. 4, an illustration of a cross-sectional view of an induction heating circuit is depicted in accordance with an illustrative embodiment. Induction heating circuit 400 is a physical implementation of first induction heating circuit 231 of FIG. 2.

Induction heating circuit 400 comprises conductor 402, susceptor 404, and magnetic field reduction 406. Susceptor 404 surrounds conductor 402. Susceptor 404 is coaxial with conductor 402. Although susceptor 404 is depicted as a sleeve, susceptor 404 can take any desirable form. In some illustrative examples, susceptor 404 takes the form of a spiral, a coil, multiple short sleeves, or any other desirable form to surround conductor 402.

Magnetic field reduction 406 takes the form of shielding 408. Shielding 408 surrounds susceptor 404. In this illustrative example, shielding 408 comprises first layer 410 and second layer 412. First layer 410 and second layer 412 comprise two different types of shielding of conductive metal selected from a spiral, a foil, and a braid. Shielding 408 blocks magnetic fields from exiting induction heating circuit 400 after susceptor 404 reaches its Curie temperature through at least one of physically blocking or blocking the magnetic fields using induced currents.

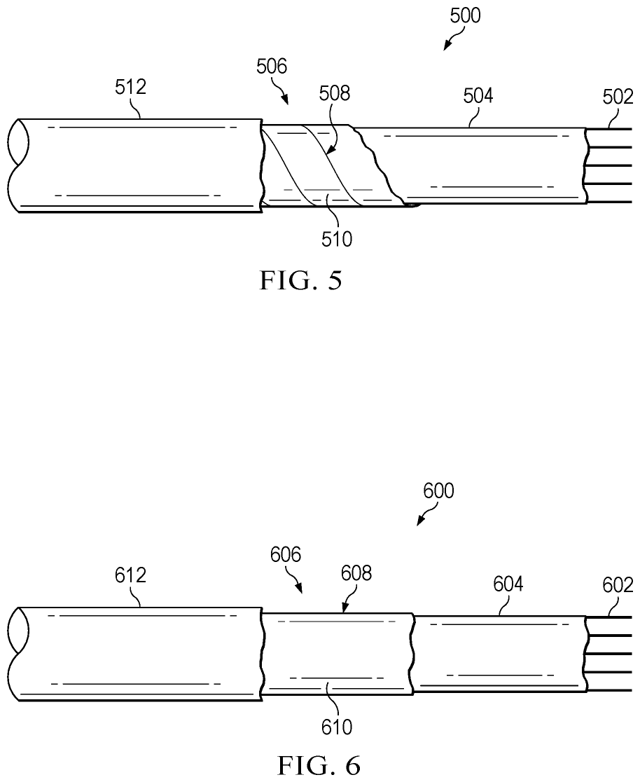

Turning now to FIG. 5, an illustration of a partially exploded view of an induction heating circuit with spiral shielding is depicted in accordance with an illustrative embodiment. Induction heating circuit 500 is physical implementation of first induction heating circuit 231 of FIG. 2. Induction heating circuit 500 is a physical implementation of induction heating circuit 300 of FIG. 3.

Induction heating circuit 500 comprises conductor 502, susceptor 504, and magnetic field reduction 506. Susceptor 504 surrounds conductor 502. Susceptor 504 is coaxial with conductor 502. Although susceptor 504 is depicted as a sleeve, susceptor 504 can take any desirable form. In some illustrative examples, susceptor 504 takes the form of a spiral, a coil, multiple short sleeves, or any other desirable form to surround conductor 502.

Magnetic field reduction 506 takes the form of shielding 508. Shielding 508 surrounds susceptor 504. In this illustrative example, shielding 508 comprises spiral 510 formed of a conductive metal. Exterior 512 provides an optional layer of polymeric material. Exterior 512 can be provided for easier handling.

Turning now to FIG. 6, an illustration of a partially exploded view of an induction heating circuit with foil shielding is depicted in accordance with an illustrative embodiment. Induction heating circuit 600 is physical implementation of first induction heating circuit 231 of FIG. 2. Induction heating circuit 600 is a physical implementation of induction heating circuit 300 of FIG. 3.

Induction heating circuit 600 comprises conductor 602, susceptor 604, and magnetic field reduction 606. Susceptor 604 surrounds conductor 602. Susceptor 604 is coaxial with conductor 602. Although susceptor 604 is depicted as a sleeve, susceptor 604 can take any desirable form. In some illustrative examples, susceptor 604 takes the form of a spiral, a coil, multiple short sleeves, or any other desirable form to surround conductor 602.

Magnetic field reduction 606 takes the form of shielding 608. Shielding 608 surrounds susceptor 604. In this illustrative example, shielding 608 comprises foil 610 formed of a conductive metal. Exterior 612 provides an optional layer of polymeric material. Exterior 612 can be provided for easier handling.

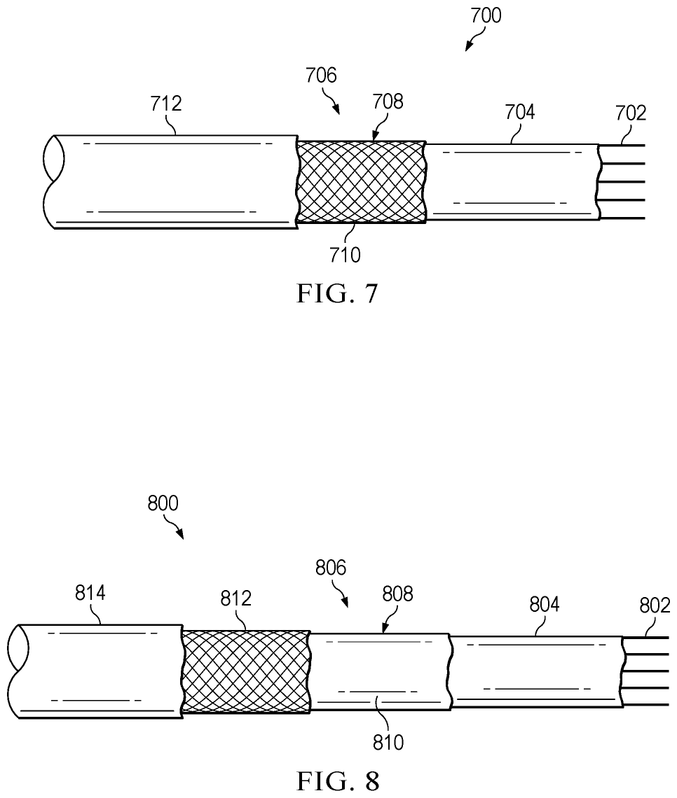

Turning now to FIG. 7, an illustration of a partially exploded view of an induction heating circuit with braided shielding is depicted in accordance with an illustrative embodiment. Induction heating circuit 700 is physical implementation of first induction heating circuit 231 of FIG. 2. Induction heating circuit 700 is a physical implementation of induction heating circuit 300 of FIG. 3.

Induction heating circuit 700 comprises conductor 702, susceptor 704, and magnetic field reduction 706. Susceptor 704 surrounds conductor 702. Susceptor 704 is coaxial with conductor 702. Although susceptor 704 is depicted as a sleeve, susceptor 704 can take any desirable form. In some illustrative examples, susceptor 704 takes the form of a spiral, a coil, multiple short sleeves, or any other desirable form to surround conductor 702.

Magnetic field reduction 706 takes the form of shielding 708. Shielding 708 surrounds susceptor 704. In this illustrative example, shielding 708 comprises braid 710 formed of a conductive metal. Exterior 712 provides an optional layer of polymeric material. Exterior 712 can be provided for easier handling.

Turning now to FIG. 8, an illustration of a partially exploded view of an induction heating circuit with foil and braided shielding in accordance with an illustrative embodiment. Induction heating circuit 800 is physical implementation of first induction heating circuit 231 of FIG. 2. Induction heating circuit 800 is a physical implementation of induction heating circuit 300 of FIG. 3.

Induction heating circuit 800 comprises conductor 802, susceptor 804, and magnetic field reduction 806. Susceptor 804 surrounds conductor 802. Susceptor 804 is coaxial with conductor 802. Although susceptor 804 is depicted as a sleeve, susceptor 804 can take any desirable form. In some illustrative examples, susceptor 804 takes the form of a spiral, a coil, multiple short sleeves, or any other desirable form to surround conductor 802.

Magnetic field reduction 806 takes the form of shielding 808. Shielding 808 surrounds susceptor 804. In this illustrative example, shielding 808 comprises first layer 810 and second layer 812. First layer 810 and second layer 812 comprise two different types of shielding of conductive metal selected from a spiral, a foil, and a braid.

In some illustrative examples, first layer 810 comprises a braid of conductive metal and second layer 812 comprises a foil of conductive metal. In the illustrated example, first layer 810 comprises a foil of conductive metal and second layer 812 comprises a braid of conductive metal. Other combinations of at least one of a spiral, a foil, and a braid can be used. Exterior 814 provides an optional layer of polymeric material. Exterior 814 can be provided for easier handling.

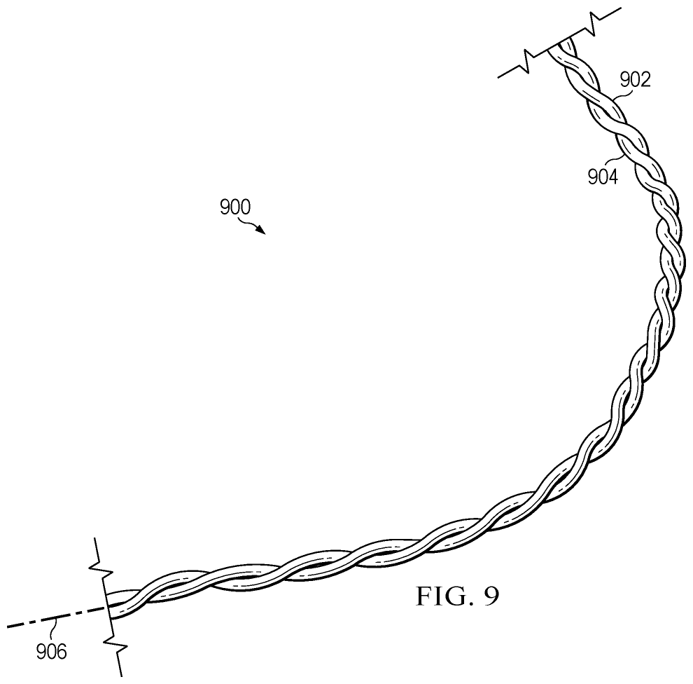

Turning now to FIG. 9, an illustration of a side view of an induction heating system with a twisted pair of induction heating circuits is depicted in accordance with an illustrative embodiment. Induction heating system 900 is a physical implementation of induction heating system 208 of FIG. 2.

Induction heating system 900 comprises first induction heating circuit 902 having a first current direction and second induction heating circuit 904 twisted around first induction heating circuit 902 and central axis 906. Second induction heating circuit 904 having a second current direction opposite from the first current direction.

In some illustrative examples, first induction heating circuit 902 and second induction heating circuit 904 are connected by a bend (not depicted) such that first induction heating circuit 902 and second induction heating circuit 904 are formed by a same conductor and a same susceptor surrounding the conductor. In some illustrative examples, first induction heating circuit 902 and second induction heating circuit 904 are formed by separate lengths of conductor surrounded by susceptor. In these illustrative examples, first induction heating circuit 902 and second induction heating circuit 904 have separate electrical buses. In some illustrative examples, the magnetic field reduction for induction heating system 900 is provided by electromagnetic cancellation of the opposite currents.

In some illustrative examples, the magnetic field reduction for induction heating system 900 is provided by both electromagnetic cancellation and shielding. In some illustrative examples, first induction heating circuit 902 and second induction heating circuit 904 each comprise shielding configured to reduce magnetic fields escaping a respective induction heating circuit when a respective susceptor is at a Curie temperature of the respective susceptor. In some illustrative examples, the shielding (not depicted) is one length and wraps around itself in induction heating system 900 due to twisting of first induction heating circuit 902 and second induction heating circuit 904. In other illustrative examples, the shielding (not depicted) for first induction heating circuit 902 and second induction heating circuit 904 are two separate lengths of shielding.

In some illustrative examples, the shielding for each of the first induction heating circuit and the second induction heating circuit comprises conductive metal and is at least one of a braid, a foil, or a spiral. In some illustrative examples, shielding is not present in induction heating system 900. In some illustrative examples, shielding can be present around only one of first induction heating circuit 902 or second induction heating circuit 904.

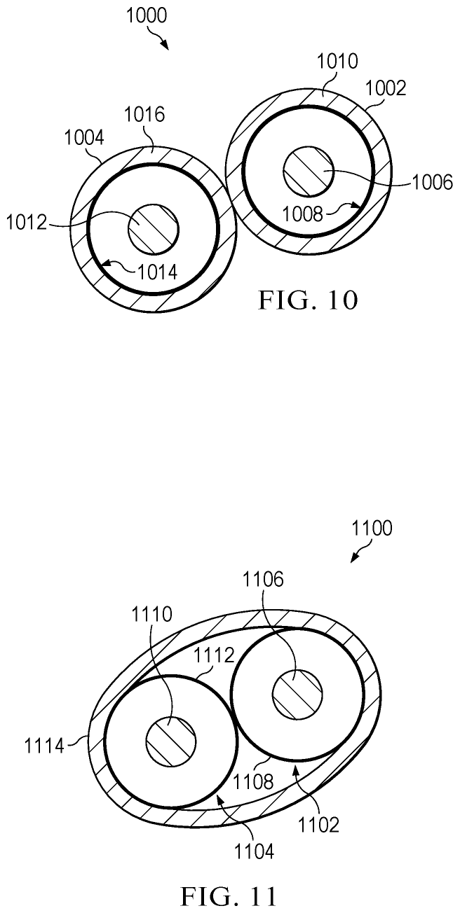

Turning now to FIG. 10, an illustration of a cross-sectional view an induction heating system with a twisted pair of induction heating circuits is depicted in accordance with an illustrative embodiment. Induction heating system 1000 is a physical implementation of induction heating system 208 of FIG. 2. In some illustrative examples, induction heating system 1000 is an implementation of induction heating system 900 with shielding around each induction heating circuit.

Induction heating system 1000 comprises pair of induction heating circuits 1001. Induction heating system 1000 comprises first induction heating circuit 1002 having a first current direction, and second induction heating circuit 1004 twisted around first induction heating circuit 1002 and central axis 1005. Second induction heating circuit 1004 has a second current direction opposite from the first current direction.

In this illustrative example, magnetic field reduction comprises the design of pair of induction heating circuits 1001 twisted around central axis 1005. Pair of induction heating circuits 1001 have opposite current directions. The opposite current directions create cancellation of magnetic fields when susceptor 1008 and susceptor 1014 reach their Curie temperature. The opposite current directions of first induction heating circuit 1002 and second induction heating circuit 1004 cancel out each other's magnetic fields.

First induction heating circuit 1002 of pair of induction heating circuits 1001 comprises conductor 1006 and susceptor 1008. In some illustrative examples, induction heating system 1000 comprises a bend (not depicted) such that pair of induction heating circuits 1001 is formed of one length of conductor and susceptor. In these illustrative examples, conductor 1006 and conductor 1012 are formed of a single length of conductive metal. In these illustrative examples, susceptor 1008 and susceptor 1014 are formed of a single length of susceptor.

In some illustrative examples, pair of induction heating circuits 1001 comprises second induction heating circuit 1004 comprising a second conductor and a second susceptor. In these illustrative examples, conductor 1006 and conductor 1012 are formed of separate lengths of conductive material. In these illustrative examples, susceptor 1008 and susceptor 1014 are formed of separate lengths of susceptor. In these illustrative examples, first induction heating circuit 1002 and second induction heating circuit 1004 utilize two separate electrical buses.

In some illustrative examples, magnetic field reduction further comprises shielding 1010 surrounding susceptor 1008. Shielding 1010 blocks magnetic fields from escaping first induction heating circuit 1002. By blocking magnetic fields, shielding 1010 reduces magnetic fields escaping induction heating system 1000.

In some illustrative examples, magnetic field reduction further comprises shielding 1016 surrounding susceptor 1014. Shielding 1016 blocks magnetic fields from escaping second induction heating circuit 1004. By blocking magnetic fields, shielding 1016 reduces magnetic fields escaping induction heating system 1000.

Shielding 1010 and shielding 1016 are formed of conductive metal. In some illustrative examples, at least one of shielding 1010 or shielding 1016 comprises a spiral of conductive metal. In some illustrative examples, at least one of shielding 1010 or shielding 1016 comprises a foil of conductive metal. In some illustrative examples, at least one of shielding 1010 or shielding 1016 comprises braid of conductive metal.

In some illustrative examples, shielding 1010 and shielding 1016 are individual and separate lengths of shielding. In some illustrative examples, shielding 1010 and shielding 1016 are connected by a bend and are part of a continuous length of shielding.

Turning now to FIG. 11, an illustration of a cross-sectional view of an induction heating circuit with a twisted pair is depicted in accordance with an illustrative embodiment. Induction heating system 1100 is a physical implementation of induction heating system 208 of FIG. 2. In some illustrative examples, induction heating system 1100 is an implementation of induction heating system 900 with shielding around both of the induction heating circuits.

Induction heating system 1100 comprises pair of induction heating circuits 1101. Induction heating system 1100 comprises first induction heating circuit 1102 having a first current direction, and second induction heating circuit 1104 twisted around first induction heating circuit 1102 and central axis 1105. Second induction heating circuit 1104 has a second current direction opposite from the first current direction.

In this illustrative example, magnetic field reduction comprises the design of pair of induction heating circuits 1101 twisted around central axis 1105. Pair of induction heating circuits 1101 have opposite current directions. The opposite current directions create cancellation of magnetic fields when susceptor 1108 and susceptor 1112 reach their Curie temperature. The opposite current directions of first induction heating circuit 1102 and second induction heating circuit 1104 cancel out each other's magnetic fields.

First induction heating circuit 1102 of pair of induction heating circuits 1101 comprises conductor 1106 and susceptor 1108. In some illustrative examples, induction heating system 1100 comprises a bend (not depicted) such that pair of induction heating circuits 1101 is formed of one length of conductor and susceptor. In these illustrative examples, conductor 1106 and conductor 1110 are formed of a single length of conductive metal. In these illustrative examples, susceptor 1108 and susceptor 1112 are formed of a single length of susceptor.

In some illustrative examples, pair of induction heating circuits 1101 comprises second induction heating circuit 1104 comprising a second conductor and a second susceptor. In these illustrative examples, conductor 1106 and conductor 1110 are formed of separate lengths of conductive material. In these illustrative examples, susceptor 1108 and susceptor 1112 are formed of separate lengths of susceptor. In these illustrative examples, first induction heating circuit 1102 and second induction heating circuit 1104 utilize two separate electrical buses.

In some illustrative examples, magnetic field reduction further comprises shielding 1114 surrounding susceptor 1108 and susceptor 1112. Shielding 1114 blocks magnetic fields from escaping first induction heating circuit 1102 and second induction heating circuit 1104. By blocking magnetic fields, shielding 1114 reduces magnetic fields escaping induction heating system 1100.

Shielding 1114 is formed of conductive metal. In some illustrative examples, shielding 1114 or comprises at least one of a spiral of conductive metal, a foil of conductive metal, or a braid of conductive metal.

In induction heating system 1100, shielding 1114 wraps around both first induction heating circuit 1102 and second induction heating circuit 1104. Shielding 1114 has a greater diameter than both shielding 1010 and shielding 1016 of FIG. 10 that encompass individual induction heating circuits.

Both induction heating system 1000 and induction heating system 1100 are depicted with shielding. However, in some non-depicted examples, an induction heating system, such as induction heating system 900 of FIG. 9, with a twisted pair of induction circuits can be utilized without shielding.

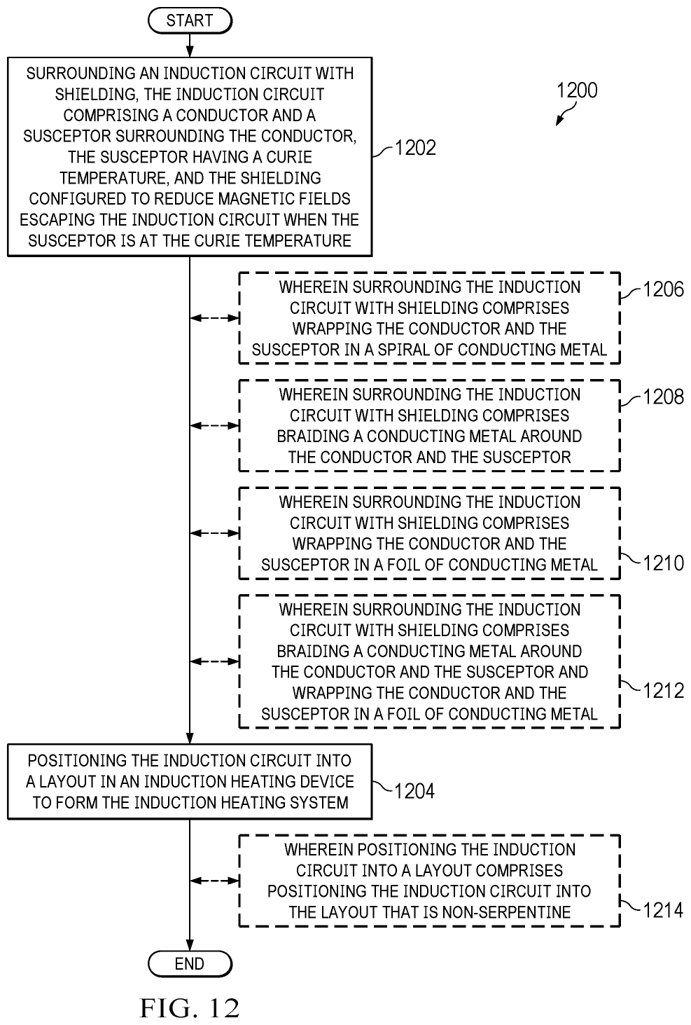

Turning now to FIG. 12, a flowchart of a method of reducing magnetic fields escaping an induction heating system during induction heating is depicted in accordance with an illustrative embodiment. Method 1200 can be used to form induction heating system 208 of FIG. 2. Method 1200 can be used to form any of induction heating circuit 300 of FIG. 3, induction heating circuit 400 of FIG. 4, induction heating circuit 500 of FIG. 5, induction heating circuit 600 of FIG. 6, induction heating circuit 700 of FIG. 7, or induction heating circuit 800 of FIG. 8.

Method 1200 surrounds an induction heating circuit with shielding, the induction heating circuit comprising a conductor and a susceptor surrounding the conductor, the susceptor having a Curie temperature, and the shielding configured to reduce magnetic fields escaping the induction heating circuit when the susceptor is at the Curie temperature (operation 1202). Method 1200 positions the induction heating circuit into a layout in an induction heating device to form the induction heating system (operation 1204). Afterwards, method 1200 terminates.

In some illustrative examples, surrounding the induction heating circuit with shielding comprises wrapping the conductor and the susceptor in a spiral of conductive metal (operation 1206). In some illustrative examples, surrounding the induction heating circuit with shielding comprises braiding a conductive metal around the conductor and the susceptor (operation 1208). In some illustrative examples, surrounding the induction heating circuit with shielding comprises wrapping the conductor and the susceptor in a foil of conductive metal (operation 1210). In some illustrative examples, surrounding the induction heating circuit with shielding comprises braiding a conductive metal around the conductor and the susceptor and wrapping the conductor and the susceptor in a foil of conductive metal (operation 1212).

In some illustrative examples, positioning the induction heating circuit into a layout comprises positioning the induction heating circuit into the layout that is non-serpentine (operation 1214). The shielding enables non-serpentine layouts of the induction heating circuit without undesirable quantities of magnetic emissions.

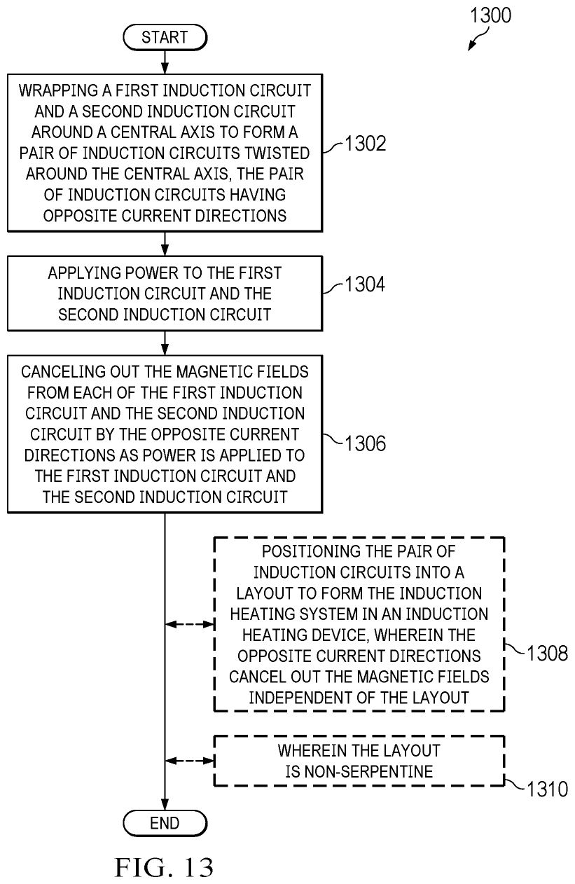

Turning now to FIG. 13, a flowchart of a method of reducing magnetic fields escaping an induction heating system during induction heating is depicted in accordance with an illustrative embodiment. Method 1300 can be used to form induction heating system 208 of FIG. 2. Method 1300 can be used to form any of induction heating system 900 of FIG. 9, induction heating system 1000 of FIG. 10, or induction heating system 1100 of FIG. 11.

Method 1300 wraps a first induction heating circuit and a second induction heating circuit around a central axis to form a pair of induction heating circuits twisted around the central axis, the pair of induction heating circuits having opposite current directions (operation 1302). Method 1300 applies power to the first induction heating circuit and the second induction heating circuit (operation 1304). Method 1300 cancels out the magnetic fields from each of the first induction heating circuit and the second induction heating circuit by the opposite current directions as power is applied to the first induction heating circuit and the second induction heating circuit (operation 1306). Afterwards, method 1300 terminates.

In some illustrative examples, method 1300 further comprises positioning the pair of induction heating circuits into a layout to form the induction heating system in an induction heating device, wherein the opposite current directions cancel out the magnetic fields independent of the layout (operation 1308). In some illustrative examples, the layout is non-serpentine (operation 1310). As used herein, the phrase “at least one of,” when used with a list of items, means different combinations of one or more of the listed items may be used and only one of each item in the list may be needed. For example, “at least one of item A, item B, or item C” may include, without limitation, item A, item A and item B, or item B. This example also may include item A, item B, and item C or item B and item C. Of course, any combinations of these items may be present. In other examples, “at least one of” may be, for example, without limitation, two of item A; one of item B; and ten of item C; four of item B and seven of item C; or other suitable combinations. The item may be a particular object, thing, or a category. In other words, at least one of means any combination items and number of items may be used from the list but not all of the items in the list are required.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step.

In some alternative implementations of an illustrative embodiment, the function or functions noted in the blocks may occur out of the order noted in the figures. For example, in some cases, two blocks shown in succession may be executed substantially concurrently, or the blocks may sometimes be performed in the reverse order, depending upon the functionality involved. Also, other blocks may be added in addition to the illustrated blocks in a flowchart or block diagram. Some blocks may be optional. For example, any of operation 1212 through operation 1218 may be optional.

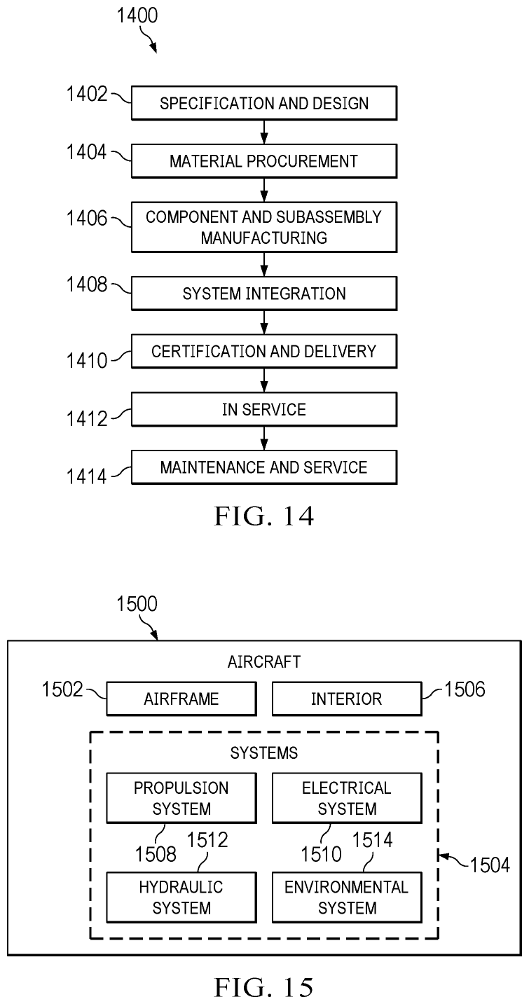

Illustrative embodiments of the present disclosure may be described in the context of aircraft manufacturing and service method 1400 as shown in FIG. 14 and aircraft 1500 as shown in FIG. 15. Turning first to FIG. 14, an illustration of an aircraft manufacturing and service method is depicted in accordance with an illustrative embodiment. During pre-production, aircraft manufacturing and service method 1400 may include specification and design 1402 of aircraft 1500 in FIG. 15 and material procurement 1404.

During production, component and subassembly manufacturing 1406 and system integration 1408 of aircraft 1500 takes place. Thereafter, aircraft 1500 may go through certification and delivery 1410 in order to be placed in service 1412. While in service 1412 by a customer, aircraft 1500 is scheduled for routine maintenance and service 1414, which may include modification, reconfiguration, refurbishment, or other maintenance and service.

Each of the processes of aircraft manufacturing and service method 1400 may be performed or carried out by a system integrator, a third party, and/or an operator. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 15, an illustration of an aircraft is depicted in which an illustrative embodiment may be implemented. In this example, aircraft 1500 is produced by aircraft manufacturing and service method 1400 of FIG. 14 and may include airframe 1502 with plurality of systems 1504 and interior 1506. Examples of systems 1504 include one or more of propulsion system 1508, electrical system 1510, hydraulic system 1512, and environmental system 1514. Any number of other systems may be included.

Apparatuses and methods embodied herein may be employed during at least one of the stages of aircraft manufacturing and service method 1400. One or more illustrative embodiments may be manufactured or used during at least one of component and subassembly manufacturing 1406, system integration 1408, in service 1412, or maintenance and service 1414 of FIG. 14.

A portion of airframe 1502 of aircraft 1500 can be formed by an induction heating circuit formed by method 1200. A portion of airframe 1502 of aircraft 1500 can be formed by method 1300. An induction heating device formed by either method 1200 or method 1300 can be used during component and subassembly manufacturing 1406. Portions of method 1300 can be performed during component and subassembly manufacturing 1406. Induction heating device 202 can be used to form a composite structure during component and subassembly manufacturing 1406. Induction heating device 202 can be used to form a composite structure during maintenance and service 1314 to form a replacement part.

The illustrative examples can enable use of Smart Susceptor heating and metal tooling for high rate production without autoclaves. The illustrative examples provide a shield for the smart susceptor magnetic field so that metal tooling can be used for high rate production rather than just non-metallic tooling.

The illustrative examples provide protection against thermal issues when using Smart Susceptor with metal tooling. In some illustrative examples, magnetic field intensity outside of an induction circuit is reduced using shielding. The shielding can take the form of at least one of foil wrap, braid sleeve, or wire wound. The shielding material can take the form of at least one of metal foil, metal coated polymer sheet, tinned copper, carbon fiber, or graphite. Adding electromagnetic shielding elements to the outside of the induction heating circuit mitigates emissions.

In one illustrative example, Litz wire arranged in a plane in alternating (counter running) directions is wrapped about a susceptor wire to shield the magnetic field of the susceptor. In another illustrative example the susceptor wires are twisted so that current can run parallel to cancel out susceptor magnetic field. In both examples, the current is running in alternate/parallel directions at the same time.

Reducing electromagnetic emissions by either shielding or twisted design of induction heating circuits allows for more flexibility on the layout of induction heating circuits within induction heating devices. The illustrative examples allow for induction heating circuits to not be constrained to parallel circuits. The illustrative examples provide for farther spacing between induction heating circuits and for larger, high amperage circuits.

If an induction heating circuit of the illustrative examples is integrated into a tooling surface, the magnetic field reduction comprising one of shielding or twisted design, will prevent or reduce unintended eddy currents. If an induction heating circuit of the illustrative examples is integrated into a tooling surface, inadvertent heating of the tool will be reduced or eliminated. Concentrating the field near the smart susceptor can improve smart susceptor heating efficiency.

A twisted wire design can be provided to provide electromagnetic cancellation. A single length of susceptor and conductor in a circuit doubling back using a bend provides cancellation. Parallel circuits formed of separate lengths of susceptor and conductor would also provide cancellation. The cancellation provided by parallel circuits can be less than the cancellation provided by a single length with a bend.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

1. An induction heating system comprising:
a conductor;
a susceptor surrounding the conductor, the susceptor having a Curie temperature; and
magnetic field reduction configured to reduce magnetic fields escaping the induction heating system when the susceptor is at the Curie temperature independent of a layout of the induction heating system within an induction heating device.

2. The induction heating system of claim 1, wherein the magnetic field reduction is shielding surrounding the susceptor.

3. The induction heating system of claim 2, wherein the shielding comprises a spiral of conductive metal.

4. The induction heating system of claim 2, wherein the shielding comprises a braid of conductive metal.

5. The induction heating system of claim 2, wherein the shielding comprises a foil of conductive metal.

6. The induction heating system of claim 2, wherein the shielding comprises copper or aluminum.

7. The induction heating system of claim 1, wherein the magnetic field reduction comprises a design of a pair of induction heating circuits twisted around a central axis, wherein the pair of induction heating circuits have opposite current directions, and wherein a first induction heating circuit of the pair of induction heating circuits comprises the conductor and the susceptor.

8. The induction heating system of claim 7, wherein the induction heating system comprises a bend such that the pair of induction heating circuits is formed of the conductor and the susceptor.

9. The induction heating system of claim 7, wherein the pair of induction heating circuits further comprises a second induction heating circuit comprising a second conductor and a second susceptor.

10. An induction heating circuit comprising:
a conductor;
a susceptor having a Curie temperature surrounding the conductor; and
a shielding of conductive metal surrounding the susceptor and the conductor configured to reduce magnetic fields escaping the induction heating circuit when the susceptor is at the Curie temperature.

11. The induction heating circuit of claim 10, wherein the shielding comprises a spiral of conductive metal.

12. The induction heating circuit of claim 10, wherein the shielding comprises a braid of conductive metal.

13-14. (canceled)

15. An induction heating system comprising:
a first induction heating circuit having a first current direction; and
a second induction heating circuit twisted around the first induction heating circuit and a central axis, the second induction heating circuit having a second current direction opposite of the first current direction.

16. The induction heating system of claim 15, wherein the first induction heating circuit and the second induction heating circuit are connected by a bend such that the first induction heating circuit and the second induction heating circuit are formed by a same conductor and a same susceptor surrounding the same conductor.

17. The induction heating system of claim 15, wherein the first induction heating circuit and the second induction heating circuit are formed by separate lengths of conductor surrounded by susceptor, the first induction heating circuit and second induction heating circuit having separate electrical buses.

18. The induction heating system of claim 15, wherein the first induction heating circuit and the second induction heating circuit each comprise shielding configured to reduce magnetic fields escaping a respective induction heating circuit when a respective susceptor is at a Curie temperature of the respective susceptor.

19. The induction heating system of claim 18, wherein the shielding for each of the first induction heating circuit and the second induction heating circuit comprises conductive metal and is at least one of a braid, a foil, or a spiral.

20. The induction heating system of claim 15, wherein the first induction heating circuit and the second induction heating circuit are a twisted pair of induction heating circuits, the induction heating system further comprising:
shielding surrounding the twisted pair of induction heating circuits, the shielding configured to reduce magnetic fields escaping the twisted pair of induction heating circuits when the twisted pair of induction heating circuits are at a Curie temperature of the twisted pair of induction heating circuits.

21. A method of forming an induction heating system with reduced magnetic fields escaping during induction heating, the method comprising:
surrounding an induction heating circuit with shielding, the shielding configured to reduce magnetic fields escaping the induction heating circuit when a susceptor of the induction heating circuit is at the Curie temperature; and
positioning the induction heating circuit into a layout in an induction heating device to form the induction heating system.

22. The method of claim 21, wherein the induction heat circuit comprises a conductor and the susceptor, wherein the susceptor surrounds the conductor, and wherein surrounding the induction heating circuit with shielding comprises wrapping the conductor and the susceptor in a spiral of conductive metal.

23. The method of claim 21, wherein the induction heat circuit comprises a conductor and the susceptor, wherein the susceptor surrounds the conductor, and wherein surrounding the induction heating circuit with shielding comprises braiding a conductive metal around the conductor and the susceptor.

24. The method of claim 21, wherein the induction heat circuit comprises a conductor and the susceptor, wherein the susceptor surrounds the conductor, and wherein surrounding the induction heating circuit with shielding comprises wrapping the conductor and the susceptor in a foil of conductive metal.

25. The method of claim 21, wherein the induction heat circuit comprises a conductor and the susceptor, wherein the susceptor surrounds the conductor, and wherein surrounding the induction heating circuit with shielding comprises braiding a conductive metal around the conductor and the susceptor and wrapping the conductor and the susceptor in a foil of conductive metal.

26. The method of claim 21, wherein positioning the induction heating circuit into a layout comprises positioning the induction heating circuit into the layout that is non-serpentine.

27. A method of reducing magnetic fields escaping an induction heating system during induction heating, the method comprising:
wrapping a first induction heating circuit and a second induction heating circuit around a central axis to form a pair of induction heating circuits twisted around the central axis, the pair of induction heating circuits having opposite current directions;
applying power to the first induction heating circuit and the second induction heating circuit; and
canceling out the magnetic fields from each of the first induction heating circuit and the second induction heating circuit by the opposite current directions as power is applied to the first induction heating circuit and the second induction heating circuit.

28.-29. (canceled)

30. A method of reducing magnetic fields escaping from an induction heating system during induction heating, the method comprising:
applying power to an induction heating circuit of the induction heating system to generate heat; and
blocking magnetic fields from exiting the induction heating circuit of the induction heating system when the susceptor is at the Curie temperature using shielding surrounding the induction heating circuit.

31. The method of claim 30, wherein blocking the magnetic fields comprises physically blocking the magnetic fields using the shielding surrounding the induction heating circuit.

32. The method of claim 30, wherein blocking the magnetic fields comprises blocking the magnetic fields using an induced current with an opposing field in the shielding after the susceptor reaches the Curie temperature.

33. The method of claim 30, wherein blocking the magnetic fields comprises blocking the magnetic fields using conductive metal at least one of wrapped or braided around a conductor and a susceptor of the induction heating circuit to form the shielding surrounding the induction heating circuit.
